(19) United States
(12) Patent Application Publication
(10) Pub. No.: US 2003/0020365 A1
(43) Pub. Date: Jan. 30, 2003

(54) Piezoelectric thin film vibrator and method of adjusting its frequency

(75) Inventors: Yuka Yamada, Kawasaki-shi (JP); Takehito Yoshida, Kawasaki-shi (JP); Masahiko Hashimoto, Shijonawate-shi (JP); Nobuyasu Suzuki, Kawasaki-shi (JP); Toshiharu Makino, Kawasaki-shi (JP)

Correspondence Address: BROWDY AND NEIMARK, P.L.L.C., 624 NINTH STREET, NW, SUITE 300, WASHINGTON, DC, 20001-5303, US

(73) Assignee: Matsushita Electric Industrial Co., Ltd., Osaka (JP)

(21) Appl. No.: 10/202,892

(22) Filed: Jul. 26, 2002

(30) Foreign Application Priority Data
Jul. 26, 2001 (JP) 2001-225517

(51) Int. Cl. H01L 41/08

(52) U.S. Cl. 310/311

(57) ABSTRACT

The purpose of the present invention is to finely adjust a resonance frequency with high accuracy and to produce excellent resonance characteristics in a piezoelectric thin film vibrator. The present invention is characterized in that a frequency adjusting layer is formed on the uppermost layer of the piezoelectric thin film vibrator and is irradiated with exciting energy to be gradually decreased in thickness to thereby adjust the resonance frequency. Further, the present invention is characterized in that ultrafine particles are gradually deposited on the uppermost layer of the piezoelectric thin film vibrator to thereby adjust the resonance frequency. According to the present invention, by adjusting the resonance frequency by a fine unit with high accuracy, it is possible to match the resonance frequency with a desired frequency precisely and thus to provide excellent and stable resonance characteristics.

### BACKGROUND OF THE INVENTION

1. Field of the Invention

The present invention relates to a piezoelectric thin film vibrator and a method of adjusting its frequency and in particular, to a piezoelectric thin film vibrator that can be used for a high-frequency piezoelectric device and provides excellent resonance characteristics and a method of adjusting its frequency.

2. Description of Related Art

A piezoelectric compound such as lead zirconate titanate (PZT: Pb(Zr, Ti)O₃), zinc oxide (ZnO), lithium niobate (LiNbO₃) or the like has been made into a thin film and widely applied to various kinds of piezoelectric devices using piezoelectric characteristics thereof such as a piezoelectric vibrator, a piezoelectric filter, a surface wave filter, a piezoelectric sensor, an actuator, or the like. In particular, as electronic components have been integrated and miniaturized with the recent advance of a semiconductor technology, a demand for miniaturizing the piezoelectric devices and making them into thin films has been increased and thus many researches have been conducted.

In the case where such a piezoelectric thin film vibrator is manufactured, the resonance frequency of the vibrator is varied by the accuracy when a mechanical part is formed or the like, so it is necessary to adjust the resonance frequency of the vibrator to a predetermined value. A conventional method of adjusting a frequency includes the first method in which the thickness of an upper electrode is made thin to increase a frequency to match the frequency with the predetermined value, and further the second method in which a thermosetting resin film is printed on the upper electrode with its thickness adjusted.

In the first method, however, it is difficult to produce stable resonance characteristics because a chemical reaction that the upper electrode is oxidized by atmospheric oxygen when the surface of the upper electrode is excited or the like occurs in a process for thinning the thickness of the electrode. In contrast, there is also a method of adjusting a frequency in an ultrahigh vacuum apparatus but in this case, manufacturing cost is increased and further it is difficult to match the resonance frequency with the predetermined value with high accuracy because the frequency is adjusted under conditions different from the state of use of the electronic devices. Further, in the second method, it is extremely difficult to adjust the thickness of the resin because the viscosity of the resin and printing conditions are varied and thus a problem is presented that an adjustment accuracy is very low. Still further, because variations in frequency characteristics are very large in one resin printing, it is impossible to adjust the resonance frequency within a rigorous accuracy of about 0.1% of the resonance frequency that is required of a high-frequency vibrator.

### SUMMARY OF THE INVENTION

The present invention is characterized in that a frequency adjusting layer is formed on the uppermost layer of a piezoelectric thin film vibrator and that the frequency adjusting layer is irradiated with exciting energy to be gradually decreased in thickness to thereby adjust a resonance frequency.

Further, the present invention is characterized in that ultrafine particles are deposited on the uppermost layer of the piezoelectric thin film vibrator to adjust the resonance frequency.

The present invention is a piezoelectric thin film vibrator including: a substrate; a piezoelectric thin film; a pair of electrodes; and an adjusting layer that is formed on an uppermost layer and is irradiated with exciting energy to be gradually decreased in thickness to thereby adjust a resonance frequency.

Here, further, it is preferable that a part of the substrate under the piezoelectric thin film is removed to form a cavity portion.

Further, the present invention is a piezoelectric thin film vibrator including: a substrate; a multilayer film in which at least two kinds of thin films are stacked; a piezoelectric thin film; a pair of electrodes; and an adjusting layer that is formed on an uppermost layer and is irradiated with exciting energy to be gradually decreased in thickness to thereby adjust a resonance frequency.

Here, it is preferable that the composition of one kind of thin film constituting the multilayer film is the same as that of the piezoelectric thin film.

According to the constitution described above, it is possible to produce a piezoelectric thin film vibrator whose resonance frequency is adjusted precisely.

The present invention is a piezoelectric thin film vibrator in which the composition of the adjusting layer is the same as that of the piezoelectric thin film. This constitution can simplify a manufacturing process.

Further, the present invention is a piezoelectric thin film vibrator including: a substrate; a piezoelectric thin film; a pair of electrodes; and an ultrafine particle layer that is formed on an uppermost layer so as to adjust a resonance frequency.

Here, further, it is preferable that a part of the substrate under the piezoelectric thin film is removed to form a cavity portion.

Still further, the present invention is a piezoelectric thin film vibrator including: a substrate; a multilayer film in which at least two kinds of thin films are stacked; a piezoelectric thin film; a pair of electrodes; and an ultrafine particle layer that is formed on an uppermost layer and is formed so as to adjust a resonance frequency.

Here, it is preferable that the composition of one kind of thin film constituting the multilayer film is the same as that of the piezoelectric thin film.

In the above-mentioned constitution, it is preferable that the ultrafine particle layer is formed of metal such as tungsten, molybdenum, aluminum, titanium or the like.

According to the constitution described above, it is possible to produce a piezoelectric thin film vibrator whose resonance frequency is adjusted precisely.

The present invention is a filter using any one of the piezoelectric thin film vibrators described above. According to the constitution described above, it is possible to realize a filter having excellent characteristics.

The present invention is a method of adjusting a resonance frequency that includes the steps of: forming a frequency adjusting layer on the uppermost layer of a piezoelectric thin film vibrator; and irradiating the formed frequency adjusting layer with exciting energy to decrease part of its thickness to thereby adjust a resonance frequency.

Here, it is preferable that a pulsed laser is used as the exciting energy.

According to these methods, it is possible to adjust the thickness of the adjusting layer extremely finely and thus to adjust the resonance frequency precisely.

The present invention is a method of adjusting a resonance frequency that includes the steps of: arranging a target material and a piezoelectric thin film vibrator in a reaction chamber; and irradiating the target material with beam light while introducing a background gas at a predetermined pressure into the reaction chamber to excite the target material to deposit a substance ejected from the target material on the uppermost layer of the piezoelectric thin film vibrator to thereby form an ultrafine particle layer.

Here, it is desirable that the pressure of the above-mentioned background gas ranges from 0.01 Torr to 10 Torr.

According to these methods, it is possible to form ultrafine particles preferably in a high-purity atmosphere by optimizing the interaction (collision, scattering, confinement) between the substances (mainly atoms, ions, clusters) ejected from the target by the laser irradiation and the background gas.

As described above, according to the present invention, in the piezoelectric thin film vibrator, by irradiating the frequency adjusting layer formed on the uppermost layer with exciting energy to gradually decrease its thickness or by depositing the ultrafine particles on the uppermost layer, the resonance frequency is adjusted by a fine unit with accuracy to match the resonance frequency with a desired resonance frequency precisely, which in turn can provide excellent and stable resonance characteristics.

Therefore, it is the object of the present invention to provide a piezoelectric thin film vibrator that can finely adjust the resonance frequency of the piezoelectric thin film vibrator with high accuracy and produce excellent and stable resonance characteristics, and a method of adjusting its resonance frequency.

The object and advantages of the present invention will be made clearer by the following preferred embodiments that will be described with reference to the accompanying drawings.

### BRIEF DESCRIPTION OF THE DRAWINGS

FIG. 1 is a cross-sectional view to show the structure of a piezoelectric thin film vibrator in accordance with the preferred embodiment 1 of the present invention.

FIG. 2 shows a manufacturing process of a piezoelectric thin film vibrator in accordance with the preferred embodiment 1 of the present invention.

FIG. 3 is a cross-sectional view to show the structure of a piezoelectric thin film vibrator in accordance with the preferred embodiment 2 of the present invention.

FIG. 4 is a configurational view to show an ultrafine particle manufacturing unit used for the method of the present invention.

### DETAILED DESCRIPTION OF THE PREFERRED EMBODIMENTS

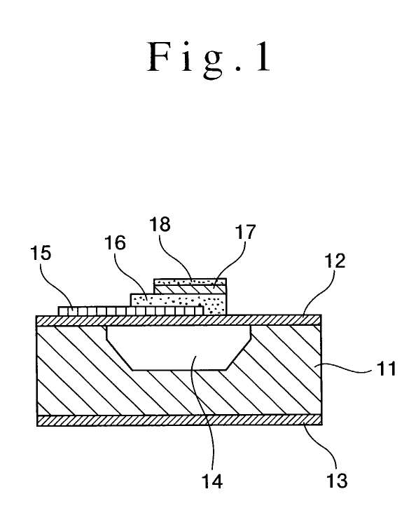

The preferred embodiments of the present invention will be hereinafter described with reference to FIG. 1 to FIG. 4.

(Preferred Embodiment 1)

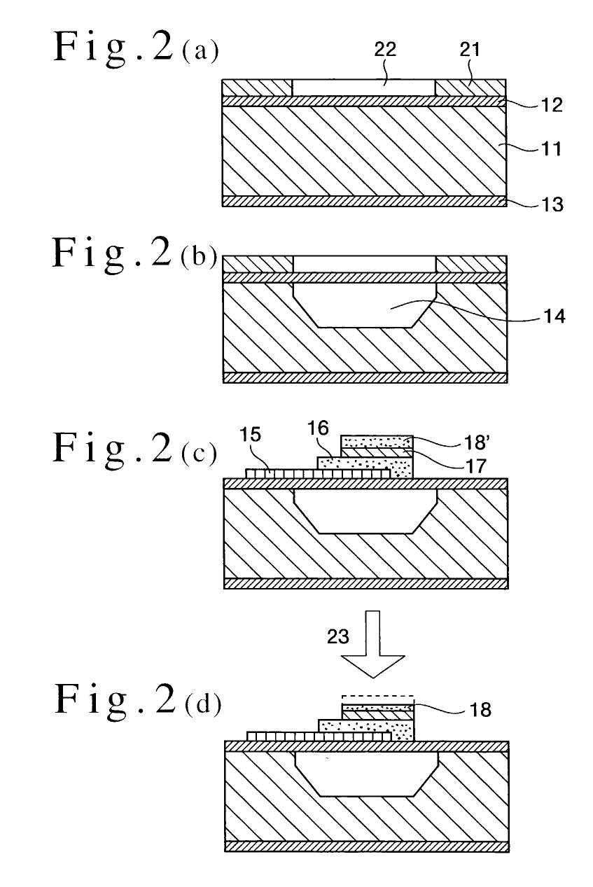

The fundamental configuration of a piezoelectric thin film vibrator of the present invention and a method of adjusting its frequency will be described in detail with reference to FIG. 1 and FIG. 2.

In the present embodiment, a piezoelectric thin film vibrator using an AlN thin film as a piezoelectric thin film will be described.

FIG. 1 is a cross-sectional view to show the structure of a piezoelectric thin film vibrator. In FIG. 1, a reference numeral 11 denotes a (100) silicon substrate (Si substrate); reference numerals 12 and 13 denote insulating layers made of a silicon nitride film and formed on both surfaces of the Si substrate 11; a reference numeral 14 denotes a cavity region formed in the Si substrate 11; a reference numeral 15 denotes a lower electrode made of a gold thin film (Au thin film); a reference numeral 16 denotes a piezoelectric thin film made of AlN; a reference numeral 17 denotes an upper electrode made of an Au thin film; and a reference numeral 18 denotes an adjusting layer made of an AlN thin film.

In the piezoelectric thin film vibrator having the above-mentioned configuration, when an electric field is applied to the piezoelectric thin film vibrator via the lower electrode 15 of the piezoelectric thin film 16 and the upper electrode 17 thereof, a portion sandwiched between the lower electrode 15 and the upper electrode 17 is vibrated in the direction of thickness. At this time, since the cavity region 14 is formed in the lower portion of the piezoelectric thin film 16, a piezo-electro converting operation can be efficiently conducted without causing a piezoelectric loss to the lower portion.

In this respect, while the silicon nitride film is used here as the insulating layers 12 and 13, a thin film made of silicon oxide, magnesium oxide, titan nitride, aluminum oxide or the like can be used. Further, while the Au thin film is used as the lower electrode 15 and the upper electrode 17, tungsten (W), molybdenum, platinum, aluminum, titanium/platinum, chromium/gold, titanium/chromium or the like can be used, and needless to say, different thin films can be used for the lower electrode 15 and the upper electrode 17. Still further, while the AlN thin film is used as the piezoelectric thin film 16 and the adjusting layer 18, multi-element based piezoelectric oxide such as a thin film made of ZnO, PZT, BaTiO₃, LiNbO₃, KNbO₃, LiTaO₃ or the like can be used.

Further, while the same AlN thin film as the piezoelectric thin film 16 is used as the adjusting layer 18, it is also recommended to use a thin film that is different from the piezoelectric thin film 16 and is made of silicon nitride, silicon oxide, magnesium oxide, titanium nitride, aluminum oxide or the like.

Next, a method of manufacturing a piezoelectric thin film vibrator constituted in the manner described above and a method of adjusting its frequency will be specifically described with reference to FIG. 2. First, insulating layers 12 and 13 are made of a silicon nitride film by a CVD (chemical vapor deposition) method. Next, a resist layer 21 is formed on the insulating layer 12 and then an aperture 22 is formed in the resist layer 21 by a photolithography method (see FIG. 2(a)). The upper surface of the Si substrate 11 at a position where the piezoelectric thin film is deposited is subjected to an anisotropic etching by using the resist layer 21 formed in this manner as an etching mask to form the cavity region 14 (FIG. 2(b)). Here, after the cavity region 14 is formed, the resist layer 21 is removed. Next, an Au thin film is selectively formed as the lower electrode 15 by the vapor deposition method or the like, and an AlN thin film is formed thereon as the piezoelectric thin film 16 by the sputtering method, and further an Au thin film is formed thereon as the upper electrode 17 by the vapor deposition method or the like. Further, an AlN thin film is formed as an adjusting layer 18′ by the sputtering method (FIG. 2(c)). Thereafter, the extra thickness of the layer that is formed as the adjusting layer 18′ is removed to an appropriate thickness to adjust the resonance frequency of the piezoelectric thin film vibrator to thereby make the completed adjusting layer 18 (FIG. 2(d)). In this manner, the piezoelectric thin film vibrator is manufactured.

In this regard, while the piezoelectric thin film 16 and the adjusting layer 18′ are formed by the sputtering method, it is also recommended to use the CVD method, the laser ablation method, or the like.

Next, a method of adjusting the frequency of the piezoelectric thin film vibrator of the present invention will be described. The adjustment of the resonance frequency is conducted by the use of ablation produced by irradiating the above-mentioned adjusting layer 18′ with a pulsed laser or the like. Here, the laser ablation method is the method of irradiating a target material with laser light of high energy density (pulse energy: about 0.1 J/cm² or more) to melt and separate the surface of the target material irradiated.

The feature of this method is that the surface of the target material can be removed under conditions of various kinds of gases and a wide range of gas pressure because of the excellent transmission of the laser light. Further, since this characteristic does not much depend on a melting point or a vapor pressure, in the laser ablation process, materials having different melting points and vapor pressures can be processed at the same time, which is thought to be difficult in a conventional thermal equilibrium process technology.

To be more specific, the adjusting layer 18′ is irradiated with laser pulse light 23 in the atmosphere. Here, an argon fluoride (ArF) excimer laser (wavelength: 193 nm, pulse width: 12 ns, energy density: 1 J/cm², repeat frequency: 10 Hz) was used. Here, a laser ablation phenomenon occurs on the surface of the adjusting layer 18′ to remove a part of the adjusting layer 18′. It is recommended that the thickness of the adjusting layer 18′ be gradually decreased by increasing the number of pulses of irradiated laser light and thus increasing the quantity of removed adjusting layer 18′ to change the resonance frequency so that the resonance frequency increases continuously to thereby match the resonance frequency with a desired resonance frequency as the adjusting layer 18 (FIG. 2(d)).

According to the above-mentioned embodiment, it is possible to adjust the resonance frequency without changing the structures of the piezoelectric thin film 16 and the upper electrode 17. Further, because the adjusting layer 18 formed on the upper electrode 17 acts as a protective layer, it is not necessary to take into account a change in mass caused by a chemical change such as the oxidation of the electrode. Still further, since the resonance frequency can be continuously adjusted in the atmosphere under the same conditions as the state use of the electronic devices and the quantity of removal by one pulse is small, it is possible to make a fine adjustment and thus to match the resonance frequency with the desired resonance frequency extremely precisely.

Incidentally, here, the adjusting layer 18′ is removed in the atmosphere but it is effective to blow an inert gas such as nitrogen gas or the like on the portion to be removed. This can prevent a chemical reaction at the removed portion and prevent the removed substance from adhering to the portion again.

As described above up to this point, the resonance frequency could be precisely matched with the desired resonance frequency by the method of adjusting the frequency of the piezoelectric thin film vibrator in accordance with the present embodiment. According to this method, since it is not necessary to use a vacuum unit, it is possible to simplify a manufacturing process and to reduce manufacturing cost. Further, since the resonance frequency can be continuously adjusted in the atmosphere under the same conditions as the state of use of the electronic devices and the quantity of removal by one laser pulse is small, it is possible to make a fine adjustment and thus to match the resonance frequency with the desired resonance frequency extremely precisely. Therefore, it is possible to realize an unprecedented high-frequency filter by the piezoelectric thin film vibrator produced in the manner described above. Further, the piezoelectric thin film vibrator that is produced by the present embodiment and has an adjusted resonance frequency can be applied to various kinds of piezoelectric devices such as a piezoelectric filter, a surface wave filter, a piezoelectric sensor, an actuator or the like.

In particular, in the case of a high-frequency filter of a level of 5 GHz or more, the film thickness of the piezoelectric thin film is required to be λ/2 or about 100 nm and thus a film thickness accuracy is required to be the order of angstrom. Also in this case, a try for adjusting the resonance frequency of the piezoelectric thin film vibrator was made by the method of adjusting a resonance frequency in accordance with the present embodiment. As a result, it was found that a correct resonance frequency could be obtained and that the piezoelectric thin film could sufficiently respond to a level of 5 GHz.

In this respect, here, the piezoelectric thin film vibrator having the structure in which the cavity region is formed under the piezoelectric thin film is used, but it is possible to adjust the resonance frequency precisely similarly also by using a piezoelectric thin film vibrator having the structure in which a multilayer film formed of at least two kinds of stacked thin films is formed between the piezoelectric thin film and the substrate in place of forming the cavity region. In this case, it is desirable that the multilayer film is formed of a combination of a material having a high acoustic impedance (Al₂O₃, TiO₂, Ag or the like) and a material having a low acoustic impedance (SiO₂, Si, Al or the like). Further, if one of the thin films constituting the multilayer film has the same composition as the piezoelectric thin film, it is possible to reduce the kinds of thin films to be used.

Further, while the piezoelectric thin film vibrator using a vibration mode in the direction of the thickness of the piezoelectric thin film was used here, it is possible to adjust the resonance frequency precisely similarly also by using a piezoelectric thin film vibrator utilizing a vibration mode in the direction of expansion of the piezoelectric thin film or a piezoelectric thin film vibrator utilizing a bending vibration mode of the piezoelectric thin film.

(Preferred Embodiment 2)

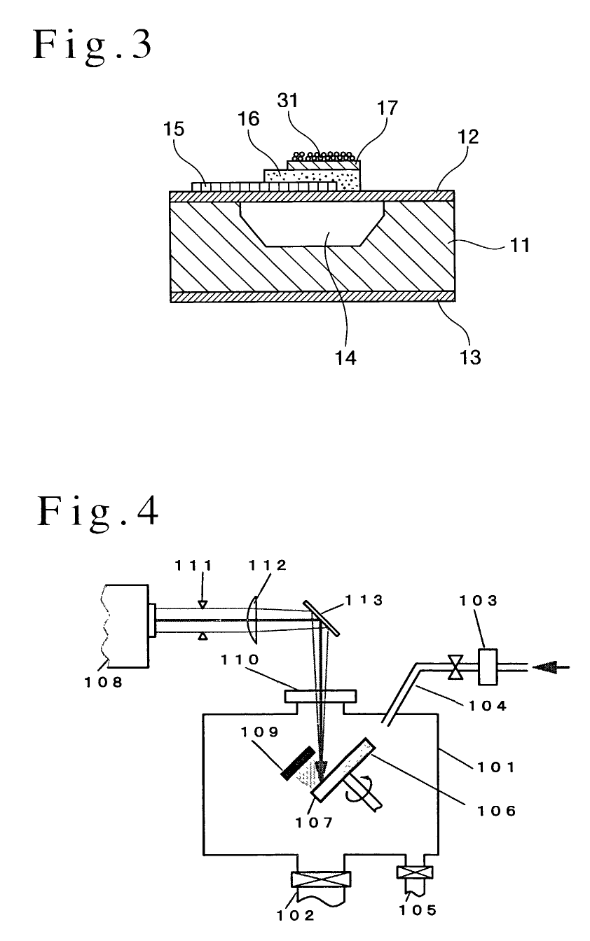

The fundamental configuration of another piezoelectric thin film vibrator in accordance with the present invention and a method of adjusting its frequency will be described in detail with reference to FIG. 3.

FIG. 3 is a cross-sectional view of the structure of a piezoelectric thin film vibrator. In FIG. 3, the configurations denoted by reference numerals 11 to 17 are the same as those in FIG. 1 described in the preferred embodiment 1. A reference numeral 31 denotes an ultrafine particle layer made of tungsten (W) and formed on an upper electrode 17.

In this respect, while W is used as the ultrafine particle layer, a metallic material can be used such as molybdenum (Mo), aluminum (Al), titanium (Ti) or the like.

Next, a method of manufacturing the piezoelectric thin film vibrator constituted in the manner described above and a method of adjusting its resonance frequency will be described. The method of manufacturing the structure to the upper electrode 17 is the same as the method described above by using FIG. 2 in the preferred embodiment 1.

Next, the method of adjusting the resonance frequency of the piezoelectric thin film vibrator in accordance with the present invention will be described. The resonance frequency is adjusted by forming the ultrafine particle layer 31. In the present embodiment, the ultrafine particle layer 31 is formed by laser ablation in the atmosphere of a rare gas (Ar, He or the like).

Since this method is a non-thermal equilibrium process, it can produce excitation selectively in space and time. While the considerably wide region or the whole region of a reaction chamber is exposed to heat or ions in the thermal process or the plasma process in the related art, this method has the selective excitation particularly in space, so that it can excite only a necessary substance source and thus produces a clean process that prevents impurities from being mixed therein. Therefore, this method is suitable for making ultrafine particles in which the mixing of impurities, composition and crystallization are controlled. Further, in this laser ablation process, deposition can be performed under conditions of various kinds of gases and a wide range of gas pressure because of the excellent transmission of the laser light as described in the preferred embodiment 1. Still further, since this characteristic does not much depend on a melting point or a vapor pressure, in the laser ablation process, materials having different melting points and vapor pressures can be processed (evaporated and deposited) at the same time, which is thought to be difficult a thermal equilibrium process technology in the related art.

FIG. 4 is a view to show an ultrafine particle forming apparatus that is used for an ultrafine particle forming method in accordance with the present invention. Here, the case will be described where the ultrafine particles are formed by the laser ablation by the use of a metallic target.

In FIG. 4, a reference numeral 101 denotes a metallic reaction chamber in which a target is arranged. An ultrahigh vacuum evacuation system 102 that evacuates air in the reaction chamber 101 to make the inside of the reaction chamber 101 to a ultra-high vacuum is provided on the bottom of the reaction chamber 101. The reaction chamber 101 is mounted with a gas introducing line 104 for supplying a background gas to the reaction chamber 101. The gas introducing line 104 is provided with a mass flow controller 103 for controlling the rate of flow of the background gas supplied to the reaction chamber 101. Further, on the bottom portion of the reaction chamber 101 is provided a gas evacuation system 105 for evacuating the background gas in the reaction chamber 101.

In the reaction chamber 101 is arranged a target holder 106 for holding a target 107. The target holder 106 is provided with a rotary shaft and the target 107 is rotated by the rotation of the rotary shaft controlled by rotation controlling section (not shown). A piezoelectric thin film vibrator 109 that is formed to the upper electrode is arranged opposite to the surface of the target 107. On the piezoelectric thin vibrator 109 is deposited a substance ejected from the target 107 that is excited by the irradiation of the laser light. Here, a metallic tungsten target is used as a target.

On the outside of the reaction chamber 101 is arranged a pulsed laser light source 108 that irradiates the target 107 with laser light as an energy beam. On the upper portion of the reaction chamber 101 is mounted a laser introducing window 110 that introduces the laser light into the reaction chamber 101. On the optical path of the laser light emitted from the pulsed laser light source 108, in the order nearer to the laser light source, are arranged a slit 111, a lens 112, and a reflecting mirror 113. The laser light emitted from the pulsed laser light source 108 is shaped by the slit 111, is focused by the lens 112, is reflected by the reflecting mirror 113, and is irradiated to the target 107 arranged in the reaction chamber 101 through the laser introducing window 110.

An operation in an ultrafine particle making apparatus having the above-mentioned configuration will be described. The reaction chamber 101 is evacuated to a vacuum of about 1.0×10⁻⁸ Torr by an ultrahigh vacuum evacuation system 102 having a turbo molecular pump as a main unit and then a He gas is introduced from the gas introducing line 104 by way of the mass flow controller 103. Here, the pressure of the rare gas in the reaction chamber 101 is set at a given pressure ranging from 0.1 Torr to 10 Torr (in the case of the He gas, preferably, from 0.01 Torr to 10 Torr) in cooperation with the operation of the gas evacuating system 105 having a dry rotary pump or a high-pressure turbo molecular pump as a main unit.

In this state, the surface of a tungsten target 107 that is arranged on the target holder 106 having a rotating mechanism and has a purity of 5N is irradiated with laser light from the pulsed laser light source 108. Here, a double harmonic of a Q-switched pulsed Nd: YAG laser (wavelength: 532 nm, pulse width: 5 ns, pulse energy: 300 mJ, repeat frequency: 10 Hz) was used. At this time, a laser ablation phenomenon occurs on the surface of the tungsten target 107 to eject ions or neutral particles (atoms, cluster) keeping a level of cluster mainly in the normal direction of the target. The ejected substances are collided with the atoms of the background rare gas to be scattered in the direction of flight, whereby their kinetic energy is scattered in the atmosphere to accelerate their association and aggregation in the air. As a result, the ejected substances grow to ultrafine particles having a particle diameter of from several nm to several tens nm and deposit on the piezoelectric thin film vibrator 109 that is arranged about 3 cm away from and opposite to the target 107. Here, the temperatures of the piezoelectric thin film vibrator and the target are not positively controlled.

In this respect, while the He gas is used here as a background gas, other inert gas such as Ar, Kr, Xe or the like may be used. In this case, it is recommended that its pressure be set such that its gaseous density is the same value as that of the He gas. For example, in the case where Ar (gaseous density: 1.78 g/l) is used as a background gas, it is recommended that the pressure be set at about 0.1 times the pressure of the He gas (gaseous density: 0.18 g/l).

In the ultrafine particle depositing process described above, it is recommended that the resonance frequency be adjusted as follows: the number of pulses of laser light to be applied is increased to increase the number of deposited ultrafine particles, thus gradually increasing the thickness of the ultrafine particle layer 31, which in turn changes a resonance frequency such that the resonance frequency decreases continuously to match the resonance frequency with a desired resonance frequency.

According to the preferred embodiment described above, it is possible to adjust the resonance frequency without changing the structures of the piezoelectric thin film 16 and the electrode 17. Further, because the rate of deposition of the ultrafine particles are small, it is possible to adjust the resonance frequency very finely and thus to match the resonance frequency with the desired resonance frequency extremely precisely.

In this respect, while the ultrafine particles are deposited at a room temperature, it is possible to heat a substrate at a temperature of 500° C. or less so as to improve crystallization. On the other hand, in some case, there is presented a problem just after the ultrafine particles are formed, they have poor crystallization, defects and the like. In such a case, to improve the quality of the film such as crystallization, purity or the like, it is effective to heat-treat the piezoelectric thin film in the atmosphere of nitrogen. If a heat treatment temperature is not more than 500° C., it is possible to prevent the ultrafine particles from being degraded by the electrode material or the internal stress of the thin film. For example, when tungsten ultrafine particles formed under a He pressure of 5.0 Torr were heat-treated in a N₂ gas, it was found that crystallization was improved.

As described above, by the method of adjusting the resonance frequency of the piezoelectric thin film vibration of the present preferred embodiment, the resonance frequency could be continuously matched with the desired value precisely. If this method is used, a fine adjustment can be performed because the quantity of deposition by one pulse is small and thus the resonance frequency can be match with the desired value extremely precisely. Further, since the size of the ultrafine particle is the order of nm and sufficiently small as compared with the wavelength of high frequency (the order of 100 nm), the effect of the ultrafine particles to the state of the surface that causes dispersion or the like can be neglected. Therefore, an unprecedented high-frequency filter can be realized by the piezoelectric thin film vibrator produced in the manner described above. Further, the piezoelectric thin film vibrator produced by in the present embodiment and having the adjusted resonance frequency can be applied to various kinds of piezoelectric devices such as a piezoelectric filter, a surface wave filter, a piezoelectric sensor, an actuator or the like.

In particular, in the case of a high-frequency filter of a level of 5 GHz or more, the film thickness of the piezoelectric thin film is required to be λ/2 or about 100 nm and thus a film thickness accuracy is required to be the order of angstrom. Also in this case, a try for adjusting the resonance frequency of the piezoelectric thin film vibrator was made by the method of adjusting a resonance frequency in accordance with the present embodiment. As a result, it was found that a precise resonance frequency could be obtained and that the piezoelectric thin film could sufficiently respond to a level of 5 GHz.

In this respect, here, the piezoelectric thin film vibrator having the structure in which the cavity region is formed under the piezoelectric thin film is used, but it is possible to adjust the resonance frequency precisely similarly also by using a piezoelectric thin film vibrator having the structure in which a multilayer film formed of at least two kinds of stacked thin films is formed between the piezoelectric thin film and the substrate in place of forming the cavity region. In this case, it is desirable that the multilayer film is formed of a combination of a material having a high acoustic impedance (Al₂O₃, TiO₂, Ag or the like) and a material having a low acoustic impedance (SiO₂, Si, Al or the like). Further, if one of the thin films constituting the multilayer film has the same composition as the piezoelectric thin film, it is possible to reduce the kinds of thin films to be used.

Further, while the piezoelectric thin film vibrator using a vibration mode in the direction of the thickness of the piezoelectric thin film was used here, it is possible to adjust the resonance frequency similarly precisely also by utilizing a piezoelectric thin film vibrator utilizing a vibration mode in the direction of expansion of the piezoelectric thin film or a piezoelectric thin film vibrator utilizing a bending vibration mode of the piezoelectric thin film.

While the present invention has been described on the basis of the preferred embodiments shown in the drawings, it is evident to those skilled in the art that the present invention may be easily modified and varied. Therefore, such modifications and variations will be also included within the spirit and scope of the present invention as defined by the appended claims.

What is claimed is:

1. A piezoelectric thin film vibrator comprising:
a substrate;
a piezoelectric thin film;
a pair of electrodes; and
an adjusting layer that is formed on an uppermost layer and is irradiated with exciting energy to be gradually decreased in thickness to thereby adjust a resonance frequency.

2. A piezoelectric thin film vibrator as claimed in claim 1, wherein a part of the substrate under the piezoelectric thin film is removed to form a cavity portion.

3. A piezoelectric thin film vibrator as claimed in claim 1, wherein the composition of the adjusting layer is the same as that of the piezoelectric thin film.

4. A piezoelectric thin film vibrator comprising:
a substrate;
a multilayer film in which at least two kinds of thin films are stacked;
a piezoelectric thin film;
a pair of electrodes; and
an adjusting layer that is formed on an uppermost layer and is irradiated with exciting energy to be gradually decreased in thickness to thereby adjust a resonance frequency.

5. A piezoelectric thin film vibrator as claimed in claim 4, wherein the composition of one kind of thin film constituting the multilayer film is the same as that of the piezoelectric thin film.

6. A piezoelectric thin film vibrator as claimed in claim 4, wherein the composition of the adjusting layer is the same as that of the piezoelectric thin film.

7. A piezoelectric thin film vibrator comprising:
a substrate;
a piezoelectric thin film;
a pair of electrodes; and
an ultrafine particle layer that is formed on an uppermost layer so as to adjust a resonance frequency.

8. A piezoelectric thin film vibrator as claimed in claim 7, wherein a part of the substrate under the piezoelectric thin film is removed to form a cavity portion.

9. A piezoelectric thin film vibrator as claimed in claim 7, wherein the ultrafine particle layer is formed of metal such as tungsten, molybdenum, aluminum, titanium or the like.

10. A piezoelectric thin film vibrator comprising:
a substrate;
a multilayer film in which at least two kinds of thin films are stacked;
a piezoelectric thin film;
a pair of electrodes; and
an ultrafine particle layer that is formed on an uppermost layer so as to adjust a resonance frequency.

11. A piezoelectric thin film vibrator as claimed in claim 10, wherein the composition of one kind of thin film constituting the multilayer film is the same as that of the piezoelectric thin film.

12. A piezoelectric thin film vibrator as claimed in claim 10, wherein the ultrafine particle layer is formed of metal such as tungsten, molybdenum, aluminum, titanium or the like.

13. A filter using a piezoelectric thin film vibrator comprising:
a substrate;
a piezoelectric thin film;
a pair of electrodes; and
an adjusting layer that is formed on an uppermost layer and is irradiated with exciting energy to be gradually decreased in thickness to thereby adjust a resonance frequency.

14. A filter using a piezoelectric thin film vibrator comprising:
a substrate;
a multilayer film in which at least two kinds of thin films are stacked;
a piezoelectric thin film;
a pair of electrodes; and
an adjusting layer that is formed on an uppermost layer and is irradiated with exciting energy to be gradually decreased in thickness to thereby adjust a resonance frequency.

15. A filter using a piezoelectric thin film vibrator comprising:
a substrate;
a piezoelectric thin film;
a pair of electrodes; and
an ultrafine particle layer that is formed on an uppermost layer so as to adjust a resonance frequency.

16. A filter using a piezoelectric thin film vibrator comprising:
a substrate;
a multilayer film in which at least two kinds of thin films are stacked;
a piezoelectric thin film;
a pair of electrodes; and
an ultrafine particle layer that is formed on an uppermost layer and is formed so as to adjust a resonance frequency.

17. A method of adjusting a resonance frequency, the method comprising the steps of:
forming a frequency adjusting layer on the uppermost layer of a piezoelectric thin film vibrator; and
irradiating the formed frequency adjusting layer with exciting energy to decrease part of its thickness to thereby adjust a resonance frequency.

18. A method of adjusting a resonance frequency as claimed in claim 17, wherein a pulsed laser is used as the exciting energy.

19. A method of adjusting a resonance frequency, the method comprising the steps of:
arranging a target material and a piezoelectric thin film vibrator in a reaction chamber; and
irradiating the target material with beam light while introducing a background gas at a predetermined pressure into the reaction chamber to excite the target material to deposit a substance ejected from the target material on the uppermost layer of the piezoelectric thin film vibrator to thereby form an ultrafine particle layer.

20. A method of adjusting a resonance frequency as claimed in claim 19, wherein the pressure of the background gas ranges from 0.01 Torr to 10 Torr.
